(19) United States
(12) Patent Application Publication
(10) Pub. No.: US 2021/0296467 A1
(43) Pub. Date: Sep. 23, 2021

(54) METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masanori Nagata, Himeji Hyogo (JP)

(21) Appl. No.: 17/007,128

(22) Filed: Aug. 31, 2020

(30) Foreign Application Priority Data
Mar. 19, 2020 (JP) 2020-050274

(51) Int. Cl. H01L 29/66; H01L 29/78; H01L 29/16; H01L 29/06; H01L 29/10; H01L 21/04

(52) U.S. Cl. CPC H01L 29/66068; H01L 29/7802; H01L 21/046; H01L 29/063; H01L 29/1095; H01L 29/1608

(57) ABSTRACT

A method for manufacturing a semiconductor device according to an embodiment includes: forming a first silicon film so as to contact a front surface, a back surface, and a side surface of a silicon carbide substrate, the back surface facing the front surface, the side surface being located between the front surface and the back surface; removing the first silicon film formed on the front surface; implanting impurities into the silicon carbide substrate from the front surface using an ion implantation method; removing the first silicon film formed on the back surface, after implanting the impurities; and performing a heat treatment for activating the impurities, after removing the first silicon film formed on the back surface.

### CROSS-REFERENCE TO RELATED APPLICATION

This application is based upon and claims the benefit of priority from Japanese Patent Application No. 2020-050274, filed on Mar. 19, 2020, the entire contents of which are incorporated herein by reference.

### FIELD

Embodiments described herein relate generally to a method for manufacturing a semiconductor device.

### BACKGROUND

Silicon carbide is expected as a material for next-generation semiconductor devices. As compared with silicon, the silicon carbide has superior physical properties such as a threefold band gap, approximately tenfold breakdown field strength, and approximately threefold thermal conductivity. By using the above characteristics, it is possible to realize a metal oxide semiconductor field effect transistor (MOSFET) capable of operating at high temperature with high breakdown voltage and low loss, for example.

In manufacturing process of a semiconductor device, an optical sensor is used for alignment of a semiconductor substrate and edge detection of the semiconductor substrate in a semiconductor manufacturing apparatus. When an optical sensor adjusted for an opaque silicon substrate is used for a transparent silicon carbide substrate, the alignment and the edge detection become difficult due to a difference in optical characteristics of the substrates. For this reason, it is difficult to process the silicon substrate and the silicon carbide substrate by the same semiconductor manufacturing apparatus.

### BRIEF DESCRIPTION OF THE DRAWINGS

FIG. 1 is a schematic cross-sectional view of a semiconductor device manufactured by a method for manufacturing a semiconductor device according to a first embodiment;

FIGS. 2A and 2B are schematic views showing the method for manufacturing the semiconductor device according to the first embodiment;

FIG. 3 is a schematic cross-sectional view showing the method for manufacturing the semiconductor device according to the first embodiment;

FIG. 4 is a schematic cross-sectional view showing the method for manufacturing the semiconductor device according to the first embodiment;

FIG. 5 is a schematic cross-sectional view showing the method for manufacturing the semiconductor device according to the first embodiment;

FIG. 6 is a schematic cross-sectional view showing the method for manufacturing the semiconductor device according to the first embodiment;

FIG. 7 is a schematic cross-sectional view showing the method for manufacturing the semiconductor device according to the first embodiment;

FIG. 8 is a schematic cross-sectional view showing the method for manufacturing the semiconductor device according to the first embodiment;

FIG. 9 is a schematic cross-sectional view showing the method for manufacturing the semiconductor device according to the first embodiment;

FIG. 10 is a schematic cross-sectional view showing the method for manufacturing the semiconductor device according to the first embodiment;

FIG. 11 is a schematic cross-sectional view showing the method for manufacturing the semiconductor device according to the first embodiment;

FIG. 12 is a schematic cross-sectional view showing the method for manufacturing the semiconductor device according to the first embodiment;

FIG. 13 is a schematic cross-sectional view showing the method for manufacturing the semiconductor device according to the first embodiment;

FIG. 14 is a schematic cross-sectional view showing the method for manufacturing the semiconductor device according to the first embodiment;

FIG. 15 is a schematic cross-sectional view showing the method for manufacturing the semiconductor device according to the first embodiment;

FIG. 16 is a schematic cross-sectional view showing the method for manufacturing the semiconductor device according to the first embodiment;

FIG. 17 is a schematic cross-sectional view showing a method for manufacturing a semiconductor device according to a second embodiment;

FIG. 18 is a schematic cross-sectional view showing the method for manufacturing the semiconductor device according to the second embodiment;

FIG. 19 is a schematic cross-sectional view showing the method for manufacturing the semiconductor device according to the second embodiment;

FIG. 20 is a schematic cross-sectional view showing the method for manufacturing the semiconductor device according to the second embodiment;

FIG. 21 is a schematic cross-sectional view showing the method for manufacturing the semiconductor device according to the second embodiment;

FIG. 22 is a schematic cross-sectional view showing the method for manufacturing the semiconductor device according to the second embodiment;

FIG. 23 is a schematic cross-sectional view showing the method for manufacturing the semiconductor device according to the second embodiment;

FIG. 24 is a schematic cross-sectional view showing the method for manufacturing the semiconductor device according to the second embodiment;

FIG. 25 is a schematic cross-sectional view showing the method for manufacturing the semiconductor device according to the second embodiment;

FIG. 26 is a schematic cross-sectional view showing the method for manufacturing the semiconductor device according to the second embodiment;

FIG. 27 is a schematic cross-sectional view showing the method for manufacturing the semiconductor device according to the second embodiment;

FIG. 28 is a schematic cross-sectional view showing the method for manufacturing the semiconductor device according to the second embodiment;

FIG. 29 is a schematic cross-sectional view showing a method for manufacturing a semiconductor device according to a third embodiment; and

FIGS. 30A and 30B are schematic views showing a method for manufacturing a semiconductor device according to a fourth embodiment.

### DETAILED DESCRIPTION

A method for manufacturing a semiconductor device according to an embodiment includes: forming a first silicon film so as to contact a front surface, a back surface, and a side surface of a silicon carbide substrate, the back surface facing the front surface, the side surface being located between the front surface and the back surface; removing the first silicon film formed on the front surface; implanting impurities into the silicon carbide substrate from the front surface using an ion implantation method; removing the first silicon film formed on the back surface, after implanting the impurities; and performing a heat treatment for activating the impurities, after removing the first silicon film formed on the back surface.

Hereinafter, embodiments of the present disclosure will be described with reference to the drawings. In the following description, the same or similar members are denoted by the same reference numerals and the description of the members described once may be appropriately omitted.

In addition, in the following description, notations n⁺, n, n⁻, p⁺, p, and p⁻ represent the relative magnitudes of impurity concentrations in respective conductivity types. That is, an n-type impurity concentration of n⁺ is relatively higher than an n-type impurity concentration of n and an n-type impurity concentration of n⁻ is relatively lower than the n-type impurity concentration of n. In addition, a p-type impurity concentration of p⁺ is relatively higher than a p-type impurity concentration of p and a p-type impurity concentration of p⁻ is relatively lower than the p-type impurity concentration of p. The n⁺ type and the n⁻ type may be simply described as the n types and the p⁺ type and the p⁻ type may be simply described as the p types.

The impurity concentration can be measured by secondary ion mass spectrometry (SIMS), for example. In addition, the relative magnitude of the impurity concentration can be determined from the magnitude of a carrier concentration obtained by scanning capacitance microscopy (SCM), for example. In addition, a distance such as a depth and a thickness of an impurity region can be obtained by the SIMS, for example. In addition, the distance such as the depth, the thicknesses, the width, and the spacing of the impurity region can be obtained using SCM images and measurement results of the SIMS, for example. In addition, a shape of an insulating layer can be determined by a scanning electron microscope (SEM) or a transmission electron microscope (TEM), for example.

### First Embodiment

A method for manufacturing a semiconductor device according to a first embodiment includes: forming a first silicon film so as to contact a front surface, a back surface, and a side surface of a silicon carbide substrate, the back surface facing the front surface, the side surface being located between the front surface and the back surface; and removing the first silicon film formed on the front surface. Further, the method includes: implanting impurities into the silicon carbide substrate from the front surface using an ion implantation method, after removing the first silicon film formed on the front surface; removing the first silicon film formed on the back surface, after implanting the impurities; and performing a heat treatment for activating the impurities, after removing the first silicon film formed on the back surface. Further, the method includes forming a second silicon film on the back surface, after the heat treatment.

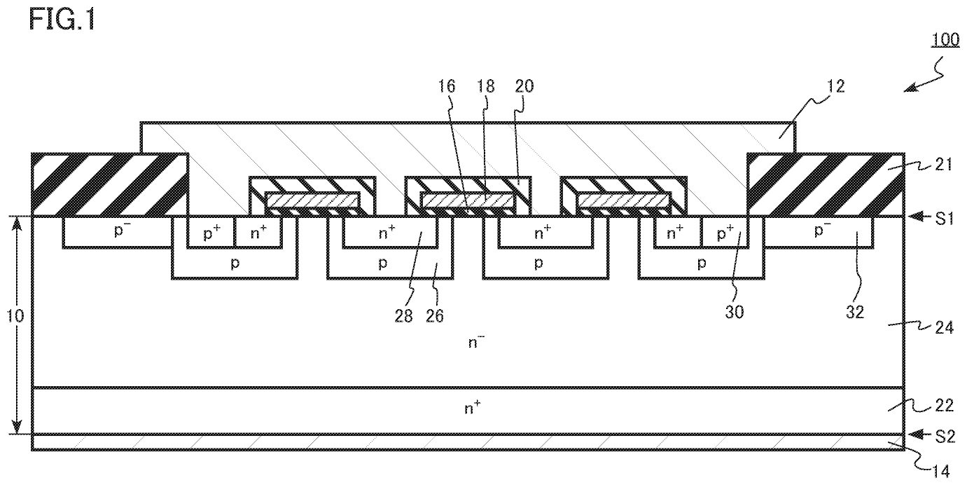

FIG. 1 is a schematic cross-sectional view of a semiconductor device manufactured by the method for manufacturing the semiconductor device according to the first embodiment.

The semiconductor device manufactured by the method for manufacturing the semiconductor device according to the first embodiment is a planar gate type vertical MOSFET 100 using silicon carbide. The MOSFET 100 is a double implantation MOSFET (DIMOSFET) in which a body region and a source region are formed by ion implantation. The MOSFET 100 is a vertical n-channel MOSFET using electrons as carriers.

The MOSFET 100 includes a silicon carbide substrate 10, a source electrode 12, a drain electrode 14, a gate insulating layer 16, a gate electrode 18, an interlayer insulating layer 20, and a peripheral insulating layer 21.

In the silicon carbide substrate 10, an n⁺-type drain region 22, an n⁻-type drift region 24, a p-type body region 26, an n⁺-type source region 28, a p⁺-type contact region 30, and a p⁻-type resurf region 32 are provided.

The silicon carbide substrate 10 is provided between the source electrode 12 and the drain electrode 14. The silicon carbide substrate 10 has a front surface S1 and a back surface S2. The silicon carbide substrate 10 is single crystal SiC. The silicon carbide substrate 10 is, for example, 4H—SiC.

The n⁺-type drain region 22 includes nitrogen (N) as n-type impurities, for example. An n-type impurity concentration of the drain region 22 is, for example, 1×10¹⁸ cm⁻³ or more and 1×10²¹ cm⁻³ or less.

The n⁻-type drift region 24 is provided between the drain region 22 and the front surface S1. The n⁻-type drift region 24 is provided on the drain region 22.

The drift region 24 includes nitrogen (N) as n-type impurities, for example. An n-type impurity concentration of the drift region 24 is lower than the n-type impurity concentration of the drain region 22. The n-type impurity concentration of the drift region 24 is, for example, 4×10¹⁴ cm⁻³ or more and 1×10¹⁷ cm⁻³ or less. A thickness of the drift region 24 is, for example, 4 μm or more and 150 μm or less.

The p-type body region 26 is provided between the drift region 24 and the front surface S1. The body region 26 functions as a channel region of the MOSFET 100.

The body region 26 includes aluminum (Al) as p-type impurities, for example. A p-type impurity concentration of the body region 26 is, for example, 1×10¹⁷ cm⁻³ or more and 5×10¹⁸ cm⁻³ or less. A depth of the body region is, for example, 0.3 μm or more and 0.8 μm or less.

The body region 26 is fixed at the potential of the source electrode 12.

The n⁺-type source region 28 is provided between the body region 26 and the front surface S1. The source region 28 includes phosphorus (P) as n-type impurities, for example. An n-type impurity concentration of the source region 28 is higher than the n-type impurity concentration of the drift region 24.

The n-type impurity concentration of the source region 28 is, for example, 5×10¹⁸ cm⁻³ or more and 1×10²¹ cm⁻³ or less. The depth of the source region 28 is smaller than the depth of the body region 26 and the depth is, for example, 0.1 μm or more and 0.3 μm or less.

The source region 28 is electrically connected to the source electrode 12. The source region 28 is fixed at the potential of the source electrode 12.

The p⁺-type contact region 30 is provided between the body region 26 and the front surface S1. A p-type impurity concentration of the contact region 30 is higher than the p-type impurity concentration of the body region 26.

The contact region 30 includes aluminum (Al) as p-type impurities, for example. A p-type impurity concentration of the contact region 30 is, for example, 5×10¹⁸ cm⁻³ or more and 1×10²¹ cm⁻³ or less.

The depth of the contact region 30 is, for example, 0.3 μm and or more and 0.6 μm or less.

The contact region 30 is electrically connected to the source electrode 12. The contact region 30 is fixed at the potential of the source electrode 12.

The p⁻-type resurf region 32 is provided between the drift region 24 and the front surface S1. The resurf region 32 is provided on the outer circumference of the body region 26. The resurf region 32 has a function of relaxing an electric field in a lateral direction at a termination portion and improving a dielectric breakdown voltage of the MOSFET 100, when the MOSFET 100 is turned off.

The gate electrode 18 is provided on the side of the front surface S1 of the silicon carbide substrate 10. The gate electrode 18 is a conductive layer. The gate electrode is, for example, polycrystalline silicon including p-type impurities or n-type impurities.

The gate insulating layer 16 is provided between the gate electrode 18 and the body region 26. The gate insulating layer 16 is, for example, silicon oxide.

A region of the body region 26 facing the gate electrode 18 functions as a channel region of the MOSFET 100.

The source electrode 12 is provided on the side of the front surface S1 of the silicon carbide substrate 10. The source electrode 12 has, for example, a stacked structure of a barrier metal layer and a main metal layer. The source electrode 12 includes a metal.

The barrier metal layer includes, for example, titanium (Ti). The barrier metal layer is, for example, titanium or titanium nitride. The barrier metal layer is, for example, titanium and titanium nitride.

The main metal layer includes, for example, aluminum (Al). The main metal layer is, for example, aluminum or aluminum alloy.

Between the source electrode 12 and the silicon carbide substrate 10, for example, a silicide layer (not shown) is provided.

The drain electrode 14 is provided on the side of the back surface S2 of the silicon carbide substrate 10. The drain electrode 14 contacts the drain region 22.

The drain electrode 14 is, for example, a metal or a metal semiconductor compound. The drain electrode 14 includes at least one material selected from the group consisting of nickel silicide, titanium (Ti), nickel (Ni), silver (Ag), and gold (Au), for example.

The interlayer insulating layer 20 is provided between the source electrode 12 and the gate electrode 18. The interlayer insulating layer 20 is, for example, silicon oxide.

The peripheral insulating layer 21 is provided between the source electrode 12 and the silicon carbide substrate 10. The peripheral insulating layer 21 is provided between the source electrode 12 and the resurf region 32. The peripheral insulating layer 21 is, for example, silicon oxide.

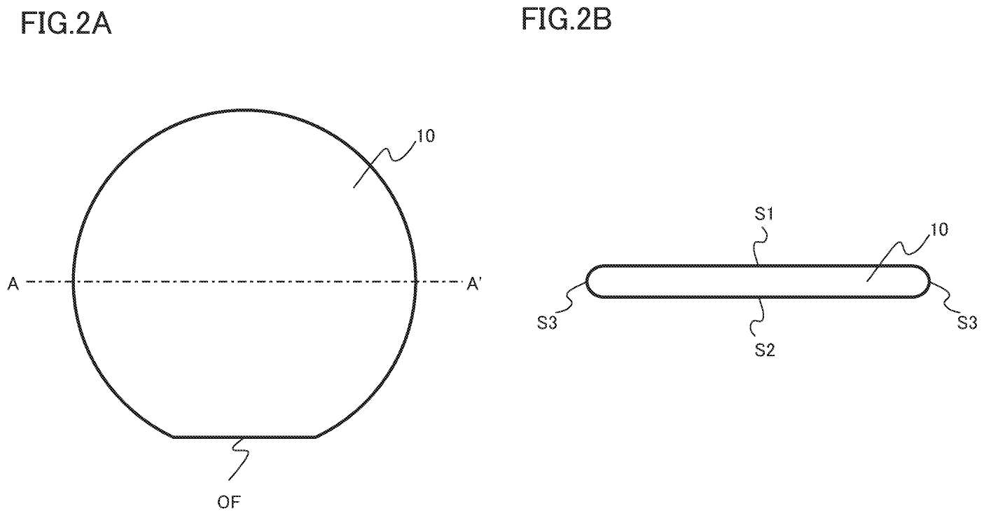

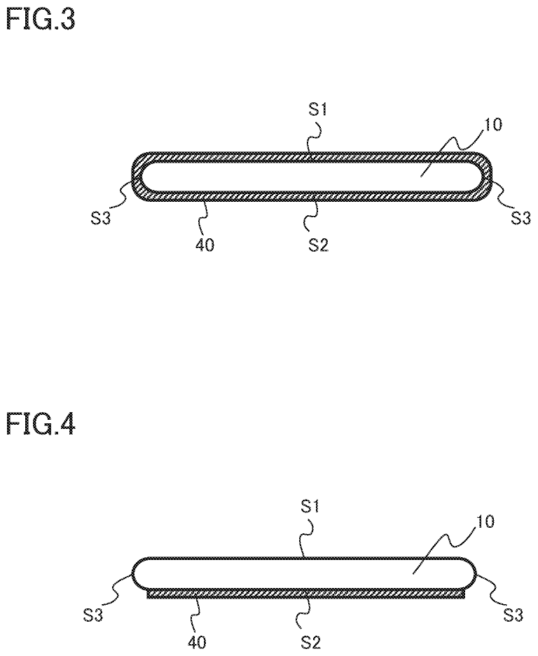

Next, a method for manufacturing the semiconductor device according to the first embodiment will be described. FIGS. 2A and 2B are schematic views showing the method for manufacturing the semiconductor device according to the first embodiment. FIGS. 2A and 2B are a plan view and a cross-sectional view, respectively. FIGS. 3 to 16 are schematic cross-sectional views showing the method for manufacturing the semiconductor device according to the first embodiment.

First, the silicon carbide substrate 10 is prepared. FIG. 2A is a plan view of the silicon carbide substrate 10 and FIG. 2B is a cross-sectional view of the silicon carbide substrate 10. FIG. 2A is a diagram of the side of the front surface of the silicon carbide substrate 10. FIG. 2B shows a cross-section taken along the line AA′ of FIG. 2A.

The silicon carbide substrate 10 is, for example, a silicon carbide wafer having an orientation flat OF. The silicon carbide substrate 10 has a front surface (“S1” in FIG. 2B), a back surface (“S2” in FIG. 2B), and a side surface (“S3” in FIG. 2B). The back surface S2 faces the front surface S1. The side surface S3 is located between the front surface S1 and the back surface S2. A thickness of the silicon carbide substrate 10 is, for example, 500 μm or more and 800 μm or less.

Next, a substrate on which a silicon film 40 is formed so as to contact the front surface S1, the back surface S2, and the side surface S3 of the silicon carbide substrate 10 is prepared. The silicon film 40 is formed so as to contact the front surface S1, the back surface S2, and the side surface S3 of the silicon carbide substrate 10 (FIG. 3). The formed silicon film 40 is in direct contact with the silicon carbide substrate 10. The silicon film 40 is an example of a first silicon film.

The direct contact of the silicon film 40 with the silicon carbide substrate 10 means that a step of forming another film on the silicon carbide substrate 10 is not actively provided before forming the silicon film 40. For example, when a natural oxide film or a native oxide film formed on the silicon carbide substrate 10 is interposed between the silicon carbide substrate 10 and the silicon film 40, it is considered that the silicon film 40 is in direct contact with the silicon carbide substrate 10.

The silicon film 40 is formed by, for example, a low pressure chemical vapor deposition method (LPCVD method). The silicon film 40 is amorphous or polycrystalline. A thickness of the silicon film 40 is, for example, 500 nm or more and 2 μm or less.

Next, the silicon film 40 formed on the front surface S1 of the silicon carbide substrate 10 is removed (FIG. 4). The silicon film 40 is removed by, for example, isotropic dry etching.

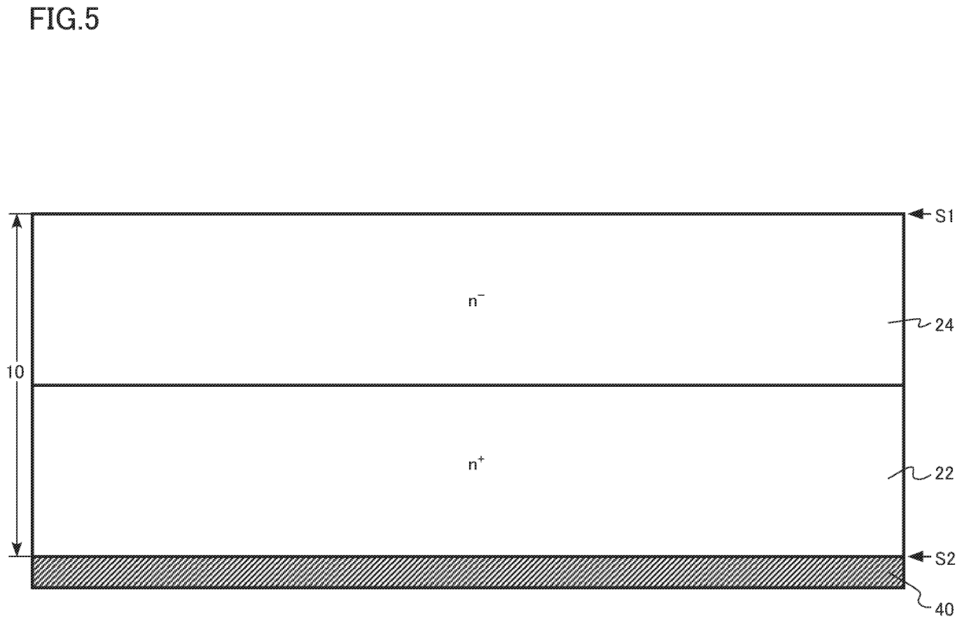

FIG. 5 is an enlarged view of a part of FIG. 4.

The silicon carbide substrate 10 has the n⁺-type drain region 22 and the n⁻-type drift region 24. An n-type impurity concentration of the drain region 22 is, for example, 1×10¹⁸ cm⁻³ or more and 1×10²¹ cm⁻³ or less. The drift region 24 is formed on the drain region 22 by an epitaxial growth method, for example. An n-type impurity concentration of the drift region 24 is, for example, 1×10¹⁵ cm⁻³ or more and 2×10¹⁶ cm⁻³ or less.

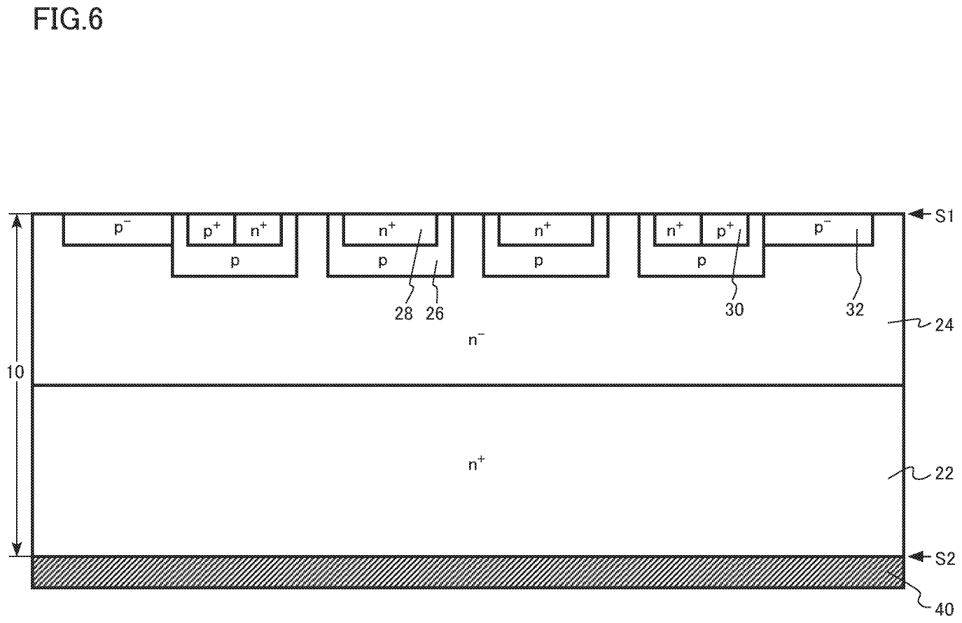

Next, the p-type body region 26, the n⁺-type source region 28, the p⁺-type contact region 30, and the p⁻-type resurf region 32 are formed in the silicon carbide substrate 10. The body region 26, the source region 28, the contact region 30, and the resurf region 32 are formed by implanting impurities from the front surface S1 of the silicon carbide substrate 10 into the silicon carbide substrate 10 by using an ion implantation method. The impurities are implanted into a predetermined region using, for example, a patterned photoresist layer (not shown) as a mask (FIG. 6). The impurities are conductive impurities. The conductive impurities are p-type impurities or n-type impurities.

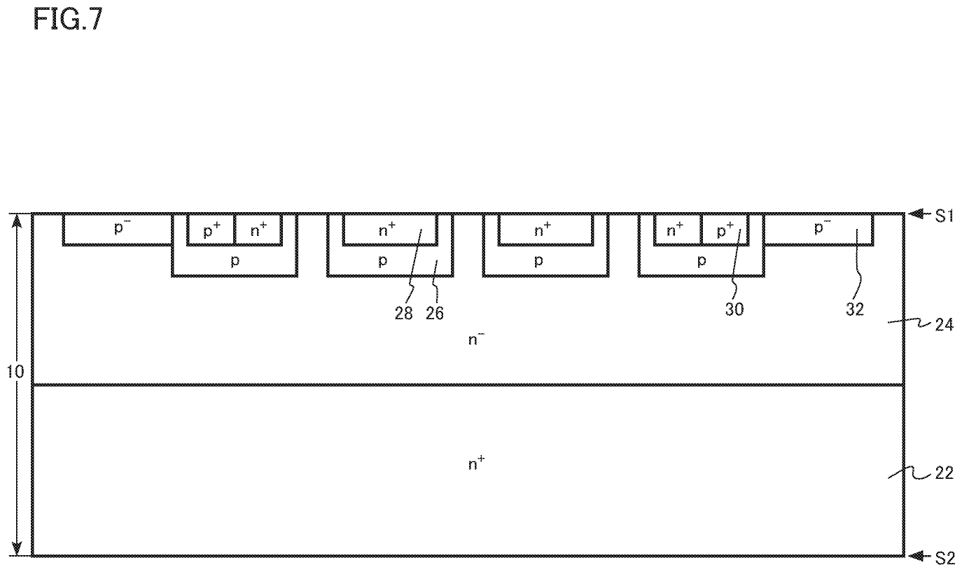

Next, the silicon film 40 formed on the back surface S2 of the silicon carbide substrate 10 is removed (FIG. 7). The silicon film 40 is removed by, for example, isotropic dry etching.

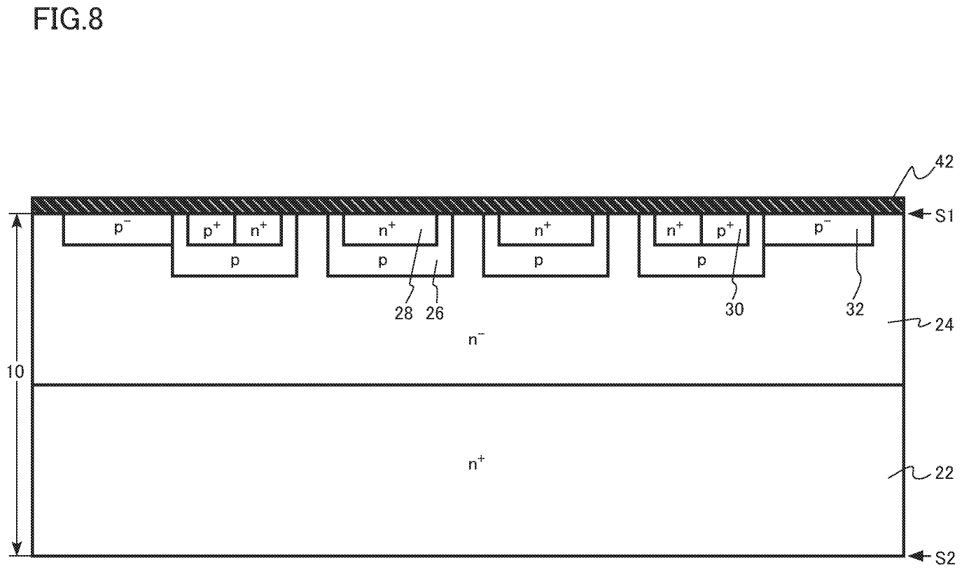

Next, a carbon film 42 is formed on the front surface S1 of the silicon carbide substrate 10 (FIG. 8). The carbon film 42 is formed by, for example, carbonization of an applied resist or a sputtering method. The carbon film 42 suppresses the front surface of the silicon carbide substrate 10 from being roughened due to carbon of the silicon carbide substrate 10 diffusing outward into the atmosphere, during a subsequent heat treatment. The carbon film 42 is a so-called cap film.

Next, the heat treatment for activating the p-type impurities and the n-type impurities implanted in the silicon carbide substrate 10 is performed. The heat treatment is performed, for example, in an inert gas atmosphere. The heat treatment is performed, for example, in an argon gas atmosphere. The temperature of the heat treatment is, for example, 1500° C. or more and 2000° C. or less. The heat treatment is so-called activation annealing.

Next, the carbon film 42 on the front surface S1 of the silicon carbide substrate 10 is removed. The carbon film 42 is removed by, for example, asking process using oxygen plasma.

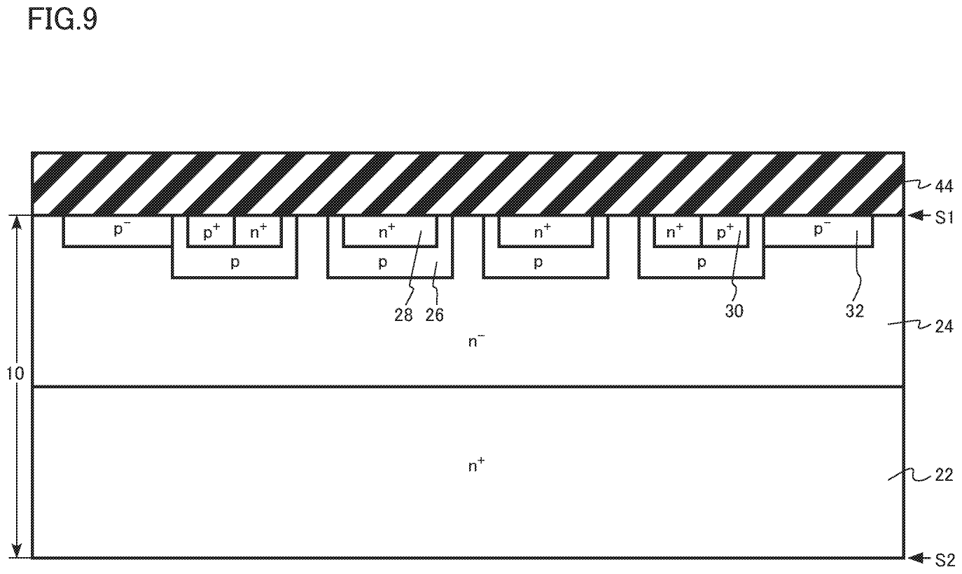

Next, a first insulating film 44 is formed on the front surface S1 of the silicon carbide substrate 10 (FIG. 9). The first insulating film 44 is formed by, for example, the LPCVD method. The first insulating film 44 is, for example, a silicon oxide film.

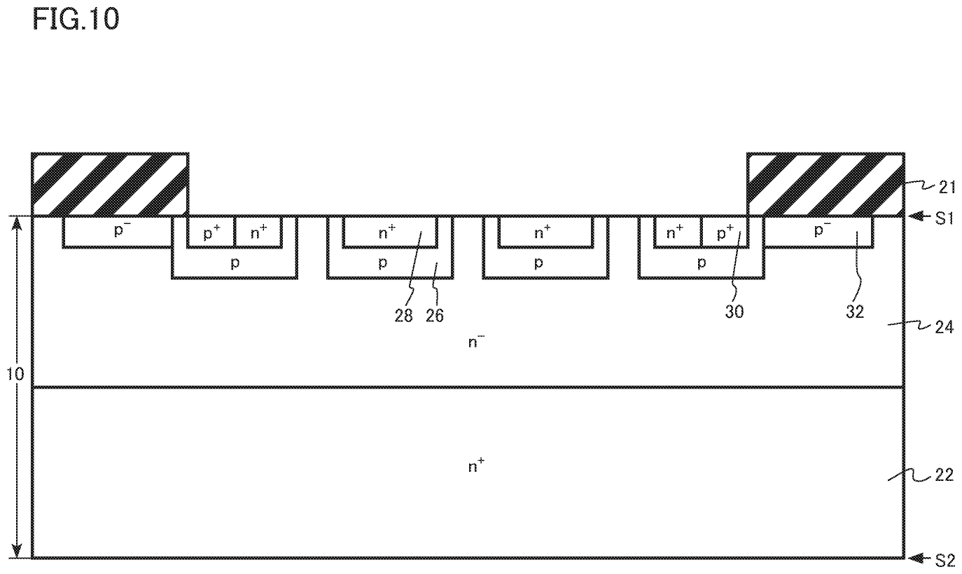

Next, the first insulating film 44 is patterned to form the peripheral insulating layer 21 (FIG. 10). The patterning of the first insulating film 44 is performed using, for example, a photolithography method and a dry etching method.

Next, a second insulating film 46 is formed on the front surface S1 of the silicon carbide substrate 10 and the peripheral insulating layer 21. The second insulating film 46 is formed by, for example, the LPCVD method. The second insulating film 46 is, for example, a silicon oxide film. A part of the second insulating film 46 finally becomes the gate insulating layer 16.

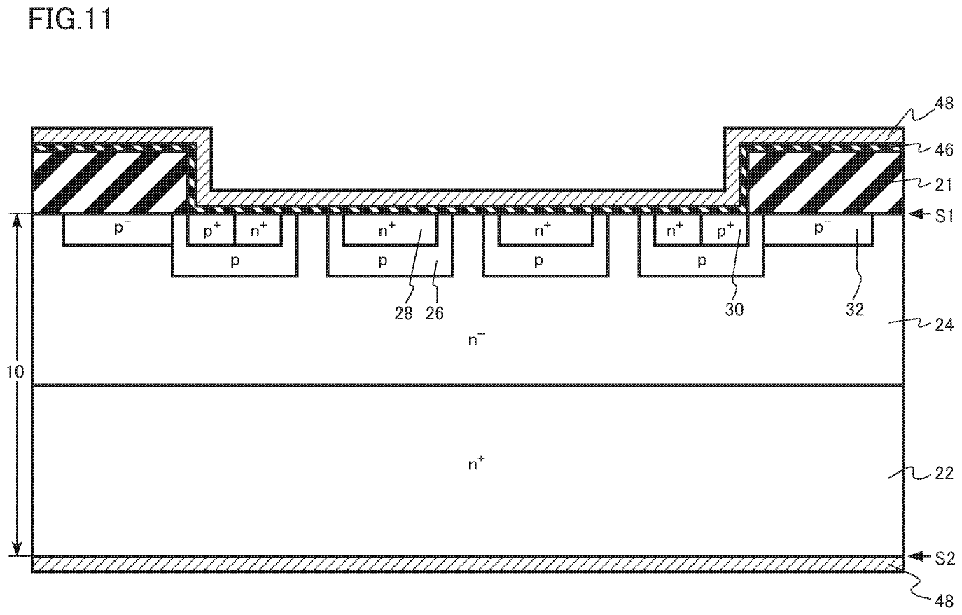

Next, a silicon film 48 is formed on the front surface S1, the back surface S2, and the side surface S3 of the silicon carbide substrate 10 (FIG. 11). The silicon film 48 is formed on the second insulating film 46. The silicon film 48 is an example of a second silicon film.

The silicon film 48 is formed by, for example, the LPCVD method. The silicon film 48 on the second insulating film 46 is amorphous or polycrystalline. The silicon film 48 includes, for example, n-type impurities or p-type impurities. A part of the silicon film 48 finally becomes the gate electrode 18.

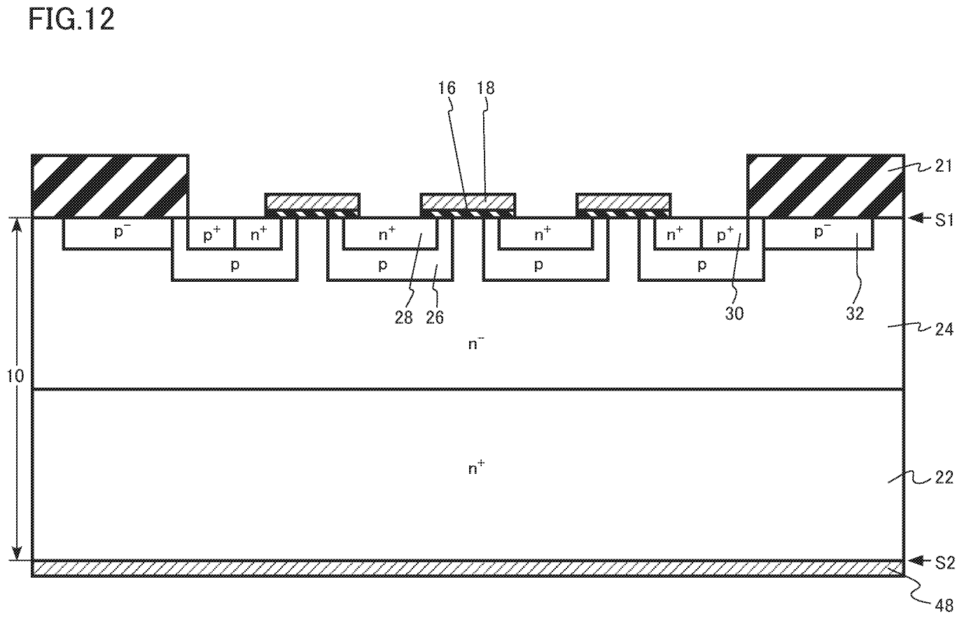

Next, the silicon film 48 on the front surface S1 of the silicon carbide substrate 10 and the second insulating film 46 are patterned (FIG. 12). The patterning of the silicon film 48 and the second insulating film 46 is performed by using, for example, the photolithography method and the dry etching method. The patterned silicon film 48 becomes the gate electrode 18. The patterned second insulating film 46 becomes the gate insulating layer 16.

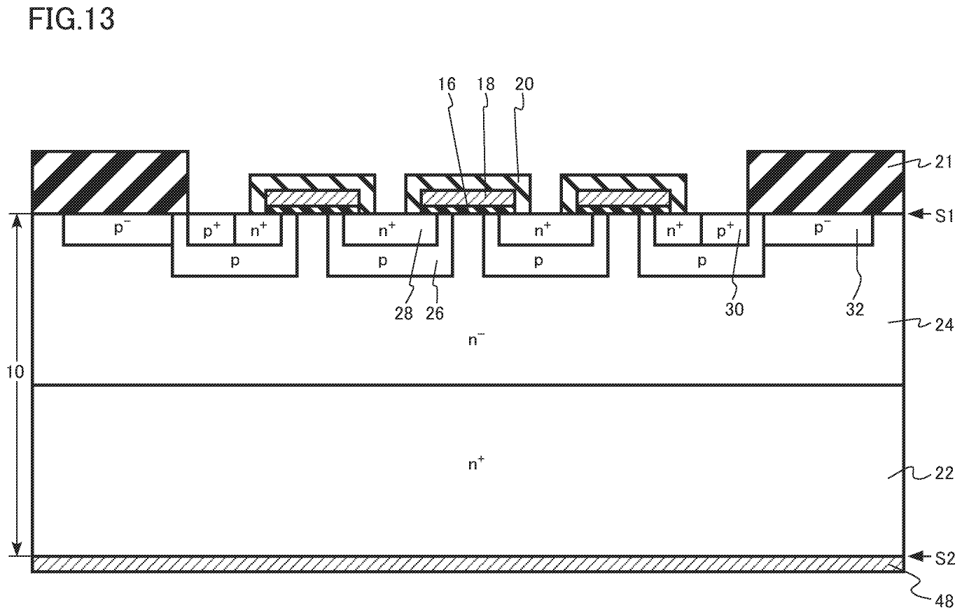

Next, the interlayer insulating layer 20 is formed on the gate electrode 18 (FIG. 13). The interlayer insulating layer 20 is formed by using, for example, the LPCVD method, the photolithography method, and the dry etching method. The interlayer insulating layer 20 is, for example, silicon oxide.

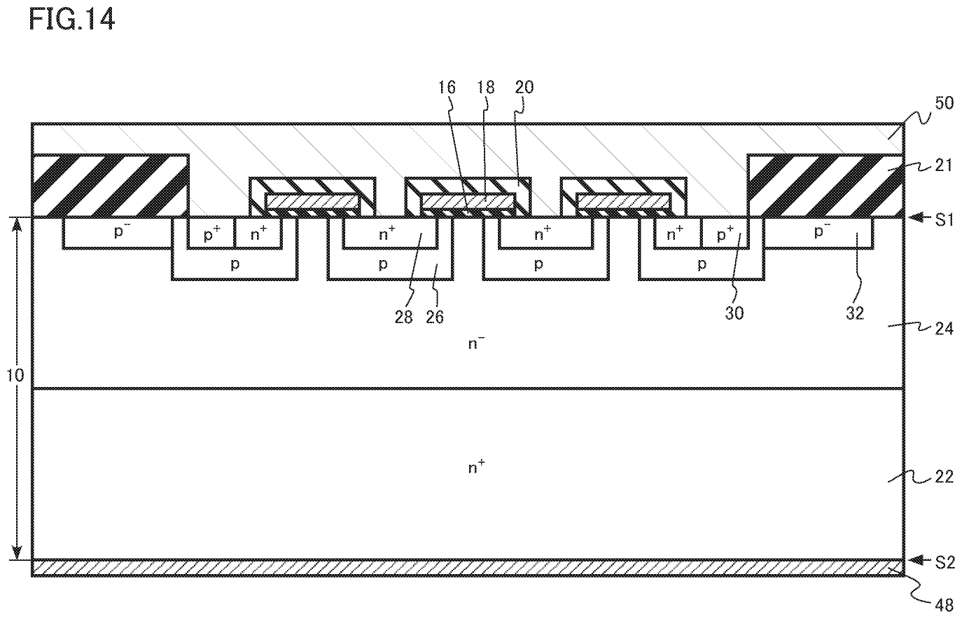

Next, a metal film 50 is formed on the front surface S1 of the silicon carbide substrate 10 (FIG. 14). The metal film 50 is formed by, for example, a sputtering method. The metal film 50 is, for example, a stacked film of a titanium nitride film and an aluminum film.

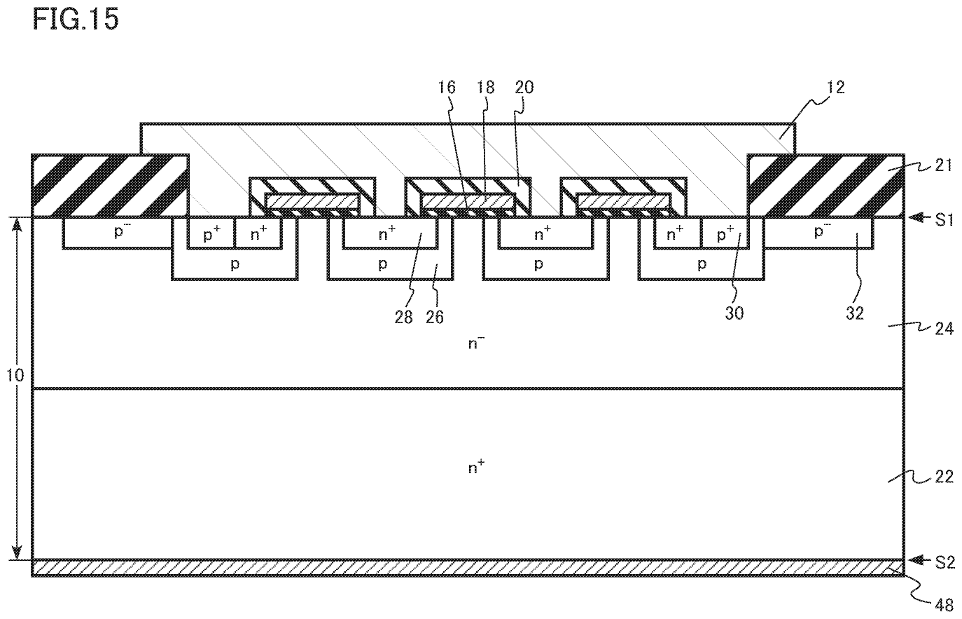

Next, the metal film 50 is patterned to form the source electrode 12 (FIG. 15). The patterning of the metal film 50 is performed by using, for example, the photolithography method and the dry etching method.

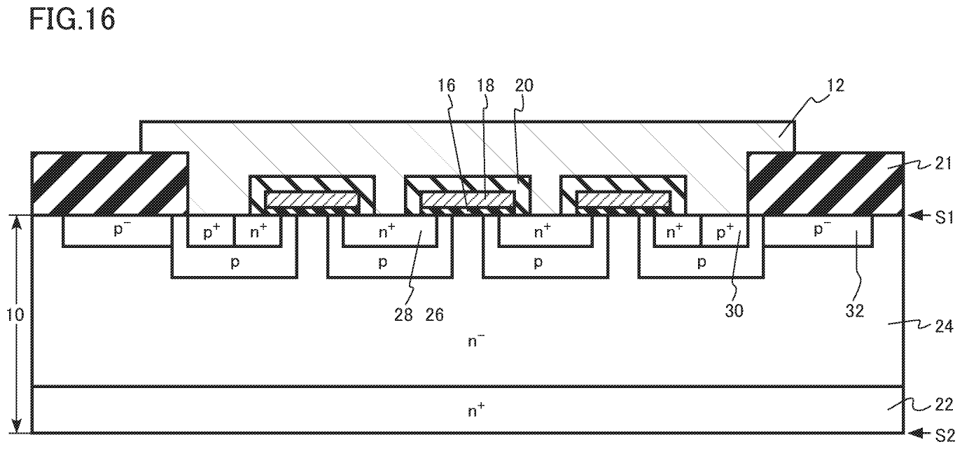

Next, back grinding of the silicon carbide substrate 10 is performed (FIG. 16). The silicon carbide substrate 10 is ground from the side of the back surface S2 to reduce the thickness of the silicon carbide substrate 10. The silicon film 48 on the back surface S2 of the silicon carbide substrate 10 is also ground and removed at the same time. The silicon carbide substrate 10 is ground to have the thickness of, for example, 5 μm or more and 200 μm or less.

Next, the drain electrode 14 is formed on the back surface S2 of the silicon carbide substrate 10. The drain electrode 14 is formed by, for example, the sputtering method. The drain electrode 14 is, for example, a metal or a metal semiconductor compound.

The MOSFET 100 shown in FIG. 1 is manufactured by the above manufacturing method.

Next, functions and effects of the MOSFET 100 according to the first embodiment will be described.

In manufacturing process of a semiconductor device, an optical sensor is used for alignment of a semiconductor substrate and edge detection of the semiconductor substrate in a semiconductor manufacturing apparatus. The semiconductor manufacturing apparatus is, for example, an exposure device for photolithography, an etching device, a film deposition device, a heat treatment device, a substrate cleaning device, a dimension measurement device, a defect inspection device, or the like.

For example, when an optical sensor adjusted for an opaque silicon substrate is used for a transparent silicon carbide substrate, the alignment and the edge detection become difficult due to a difference in optical characteristics of the substrates. For this reason, it is difficult to process the silicon substrate and the silicon carbide substrate by the same semiconductor manufacturing apparatus.

In order to process the silicon carbide substrate, it may be necessary to change the optical sensor of the semiconductor manufacturing apparatus to the optical sensor for the silicon carbide substrate.

In the method for manufacturing the semiconductor device according to the first embodiment, when the MOSFET 100 is manufactured, first, the silicon film 40 is formed on the back surface S2 of the silicon carbide substrate 10. By providing the opaque silicon film 40 on the back surface S2, it becomes possible to perform alignment and edge detection by the optical sensor for the silicon substrate in the subsequent manufacturing step. Therefore, alignment and edge detection of the silicon carbide substrate 10 are facilitated.

As a result, the silicon substrate and the silicon carbide substrate 10 can be processed by the same semiconductor manufacturing device. Therefore, for example, it becomes easy to manufacture both a silicon device and a silicon carbide device on the same manufacturing line.

Further, by providing the opaque silicon film 40 on the back surface S2, for example, back surface numbering or the like imprinted on the back surface S2 of the silicon carbide substrate 10 with a laser marker or the like is also easy to read optically.

The thickness of the silicon film 40 is preferably 500 nm or more and 2 μm or less. When the thickness of the silicon film 40 is 500 nm or more, accuracy of alignment and edge detection by the optical sensor is improved. Further, when the thickness of the silicon film 40 is 2 μm or less, deformation of the silicon carbide substrate 10 due to stress can be suppressed.

In the method for manufacturing the semiconductor device according to the first embodiment, the silicon film 40 on the back surface S2 is removed before the heat treatment for activating the p-type impurities and the n-type impurities ion-implanted into the silicon carbide substrate 10. The silicon carbide substrate 10 requires a higher temperature for the heat treatment for activating the impurities as compared with the case of the silicon substrate. For example, the temperature of 1500° C. or more are required for activation. By removing the silicon film 40 before the heat treatment, it is possible to prevent occurrence of a situation where the silicon film 40 is softened or melted and the processing of the silicon carbide substrate 10 becomes impossible.

Further, in the method for manufacturing the semiconductor device according to the first embodiment, the silicon film 48 is newly formed on the back surface S2 after the heat treatment for activating the impurities. Therefore, in the manufacturing step after the silicon film 48 is formed, alignment and edge detection can be performed by the optical sensor for the silicon substrate. The silicon film 48 is a silicon film for forming the gate electrode 18 on the front surface S1 of the silicon carbide substrate 10.

In the silicon carbide substrate 10, micropipes penetrating the silicon carbide substrate 10 may exist. The micropipes are hollow defects. If the micropipes exist, the processing of the silicon carbide substrate 10 may become impossible due to the photoresist entering the micropipes, for example. This is because the photoresist that has entered the micropipes may become a pollution source or a dust generation source.

In the method for manufacturing the semiconductor device according to the first embodiment, the silicon film 40 is formed so as to contact the front surface S1, the back surface S2, and the side surface S3 of the silicon carbide substrate 10. Therefore, even if the micropipes exist in the silicon carbide substrate 10, the micropipes can be buried with the silicon film 40. By burying the micropipes with the silicon film 40, the photoresist does not enter the micropipes, and the processing of the silicon carbide substrate 10 can be continued.

In the method for manufacturing the semiconductor device according to the first embodiment, the silicon film 48 on the back surface S2 of the silicon carbide substrate 10 is removed during the back grinding of the silicon carbide substrate 10. Therefore, it is not necessary to add a step for removing the silicon film 48 on the back surface S2.

As described above, according to the method for manufacturing the semiconductor device according to the first embodiment, the silicon film is provided on the back surface, so that it becomes possible to facilitate alignment and edge detection of the silicon carbide substrate.

### Second Embodiment

A method for manufacturing a semiconductor device according to a second embodiment is different from a method for manufacturing a semiconductor device according to the first embodiment in that a metal film is formed on a front surface after a second silicon film is removed. Hereinafter, some descriptions of the same contents as those of the method for manufacturing the semiconductor device according to the first embodiment may be omitted.

A semiconductor device manufactured by the method for manufacturing the semiconductor device according to the second embodiment is a planar gate type vertical MOSFET 100 using silicon carbide, similarly to the method for manufacturing the semiconductor device according to the first embodiment.

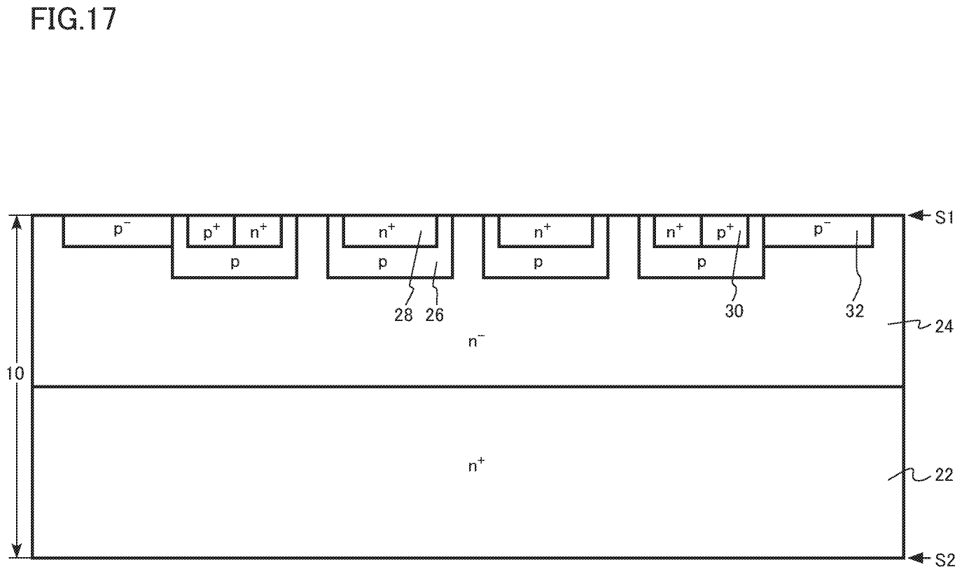

FIGS. 17 to 28 are schematic cross-sectional views showing the method for manufacturing the semiconductor device according to the second embodiment.

The same processing as the method for manufacturing the semiconductor device according to the first embodiment is performed until a carbon film 42 on a front surface S1 of a silicon carbide substrate 10 is removed, after a heat treatment for activating impurities implanted into the silicon carbide substrate 10 is performed (FIG. 17).

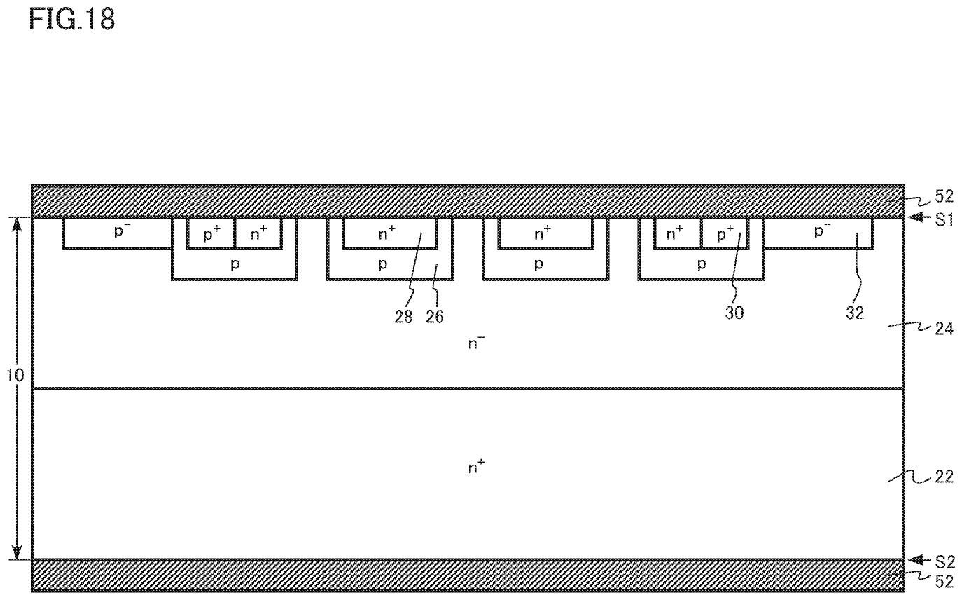

Next, a silicon film 52 is formed so as to contact a front surface S1, a back surface S2, and a side surface S3 of the silicon carbide substrate 10 (FIG. 18). The silicon film 52 is an example of a second silicon film.

The silicon film 52 is formed by, for example, a low pressure chemical vapor deposition method (LPCVD method). The silicon film 52 is amorphous or polycrystalline. A thickness of the silicon film 52 is, for example, 500 nm or more and 2 μm or less.

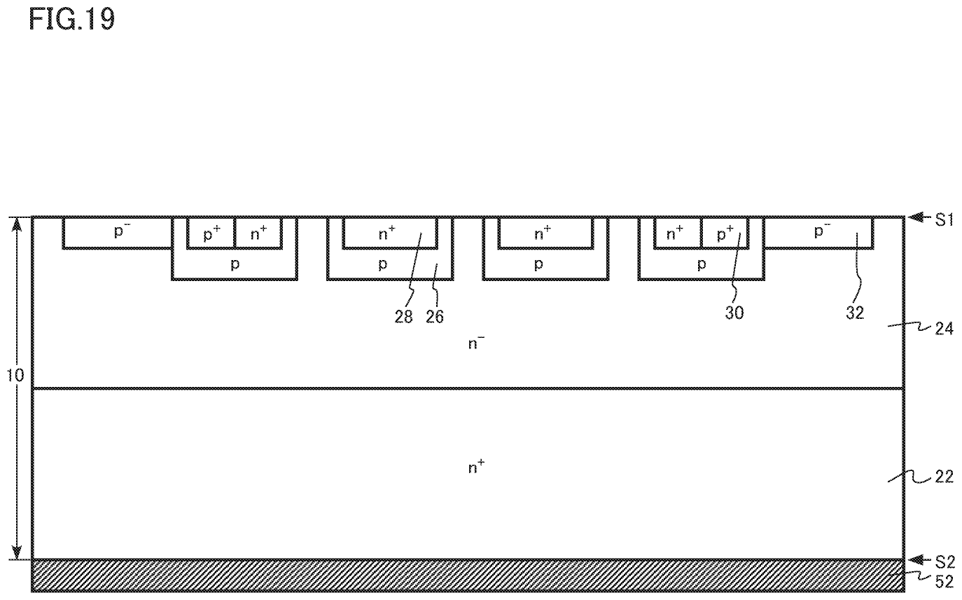

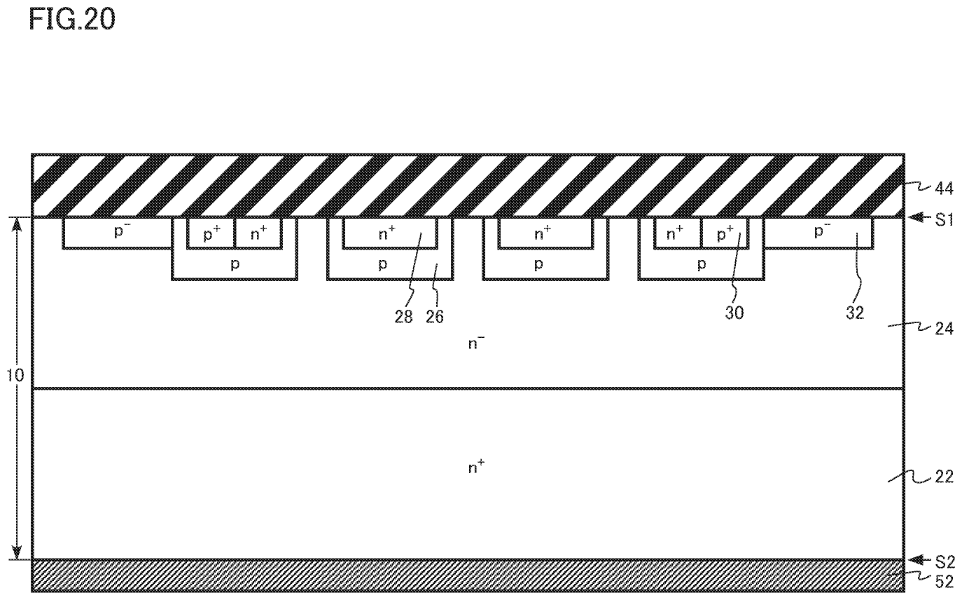

Next, the silicon film 52 formed on the front surface S1 of the silicon carbide substrate 10 is removed (FIG. 19). The silicon film 52 is removed by, for example, isotropic dry etching.

Next, a first insulating film 44 is formed on the front surface S1 of the silicon carbide substrate 10 (FIG. 20). The first insulating film 44 is formed by, for example, the LPCVD method. The first insulating film 44 is, for example, a silicon oxide film.

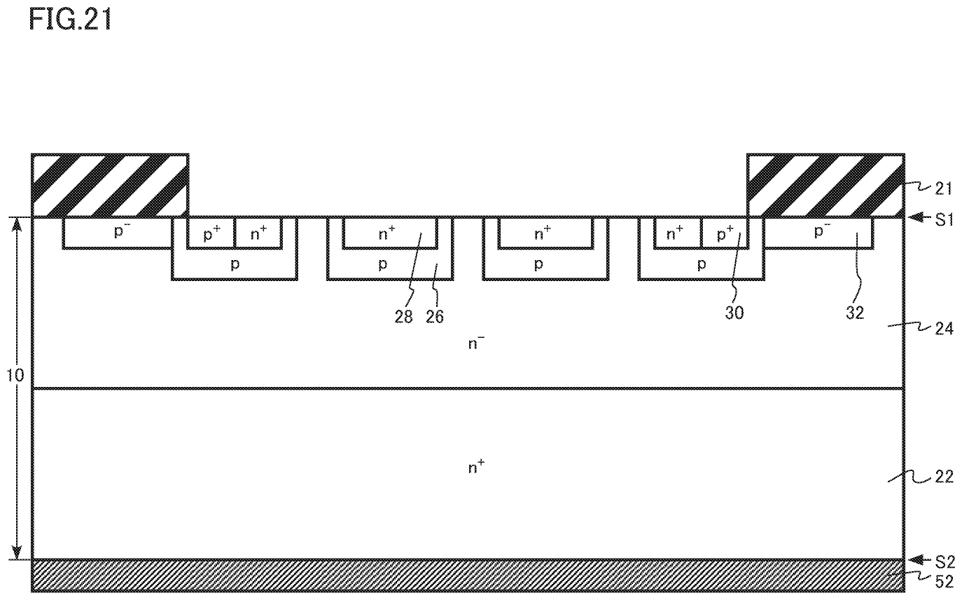

Next, the first insulating film 44 is patterned to form a peripheral insulating layer 21 (FIG. 21). The patterning of the first insulating film 44 is performed using, for example, a photolithography method and a dry etching method.

Next, a second insulating film 46 is formed on the front surface S1 of the silicon carbide substrate 10 and the peripheral insulating layer 21. The second insulating film 46 is formed by, for example, the LPCVD method. The second insulating film 46 is, for example, a silicon oxide film. A part of the second insulating film 46 finally becomes the gate insulating layer 16.

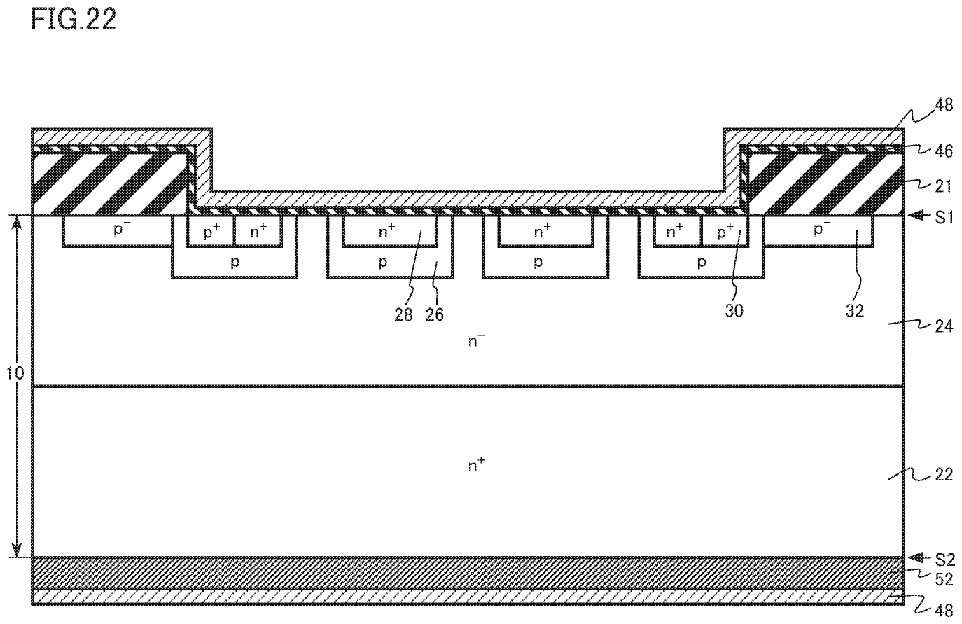

Next, a silicon film 48 is formed on the front surface S1, the back surface S2, and the side surface S3 of the silicon carbide substrate 10 (FIG. 22). The silicon film 48 is formed on the second insulating film 46. The silicon film 48 is formed on the silicon film 52 on the back surface S2.

The silicon film 48 is formed by, for example, the LPCVD method. The silicon film 48 on the second insulating film 46 is amorphous or polycrystalline. The silicon film 48 includes, for example, n-type impurities or p-type impurities. A part of the silicon film 48 finally becomes the gate electrode 18.

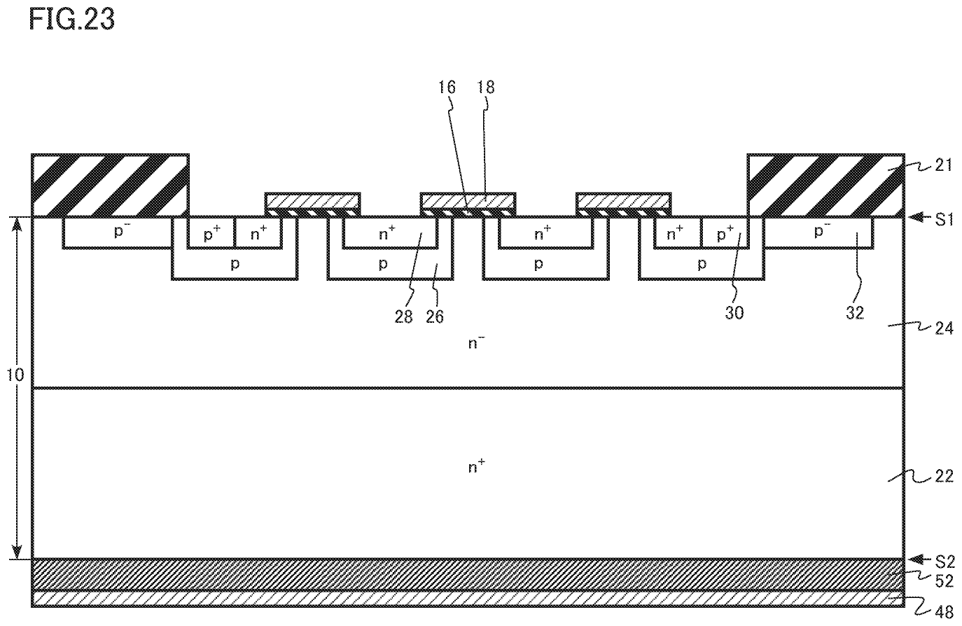

Next, the silicon film 48 on the front surface S1 of the silicon carbide substrate 10 and the second insulating film 46 are patterned (FIG. 23). The patterning of the silicon film 48 and the second insulating film 46 is performed by using, for example, the photolithography method and the dry etching method. The patterned silicon film 48 becomes the gate electrode 18. The patterned second insulating film 46 becomes the gate insulating layer 16.

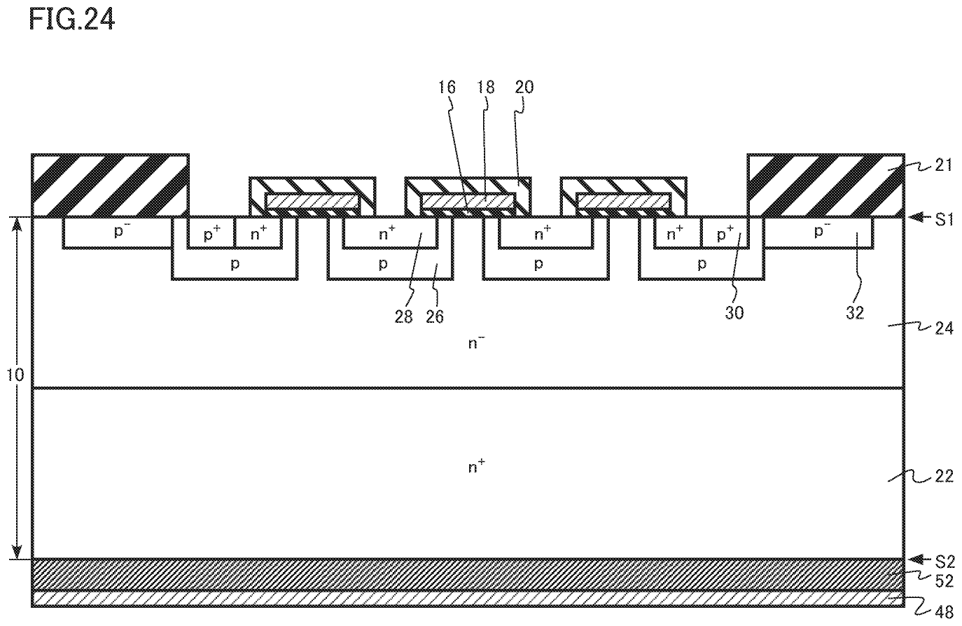

Next, an interlayer insulating layer 20 is formed on the gate electrode 18 (FIG. 24). The interlayer insulating layer 20 is formed by using, for example, the LPCVD method, the photolithography method, and the dry etching method. The interlayer insulating layer 20 is, for example, silicon oxide.

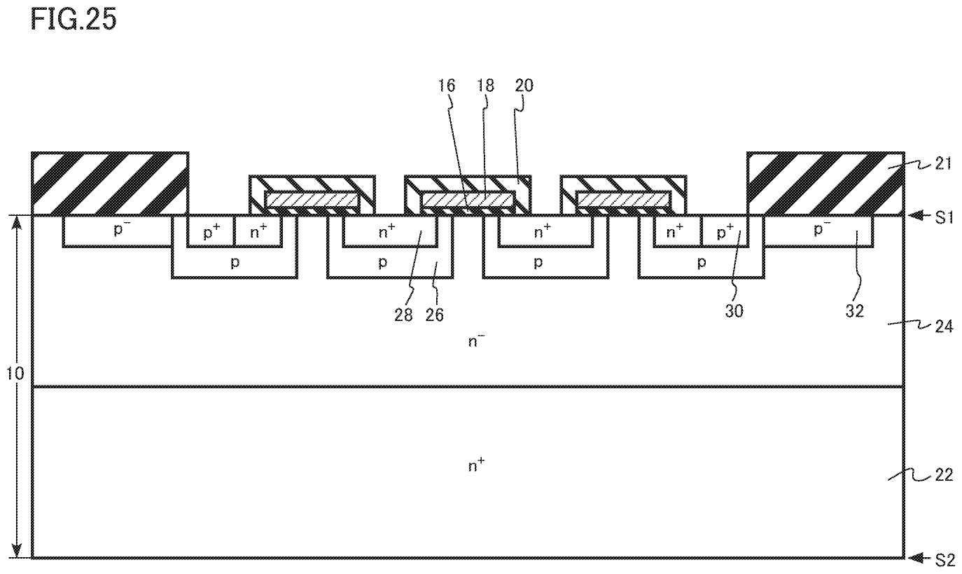

Next, the silicon film 52 and the silicon film 48 formed on the back surface S2 of the silicon carbide substrate 10 are removed (FIG. 25). The silicon film 52 and the silicon film 48 are removed by, for example, isotropic dry etching.

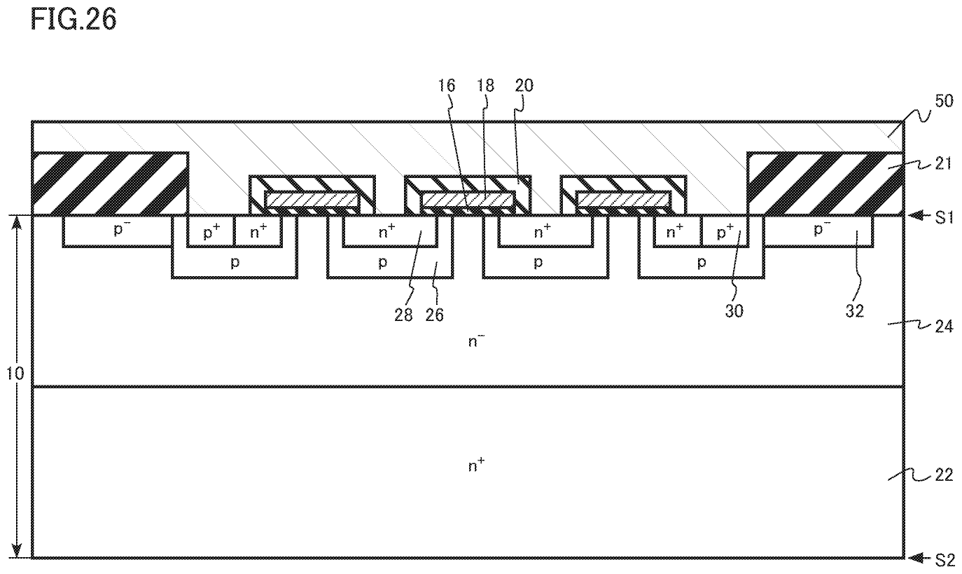

Next, a metal film 50 is formed on the front surface S1 of the silicon carbide substrate 10 (FIG. 26). The metal film 50 is formed by, for example, a sputtering method. The metal film 50 is, for example, a stacked film of a titanium nitride film and an aluminum film.

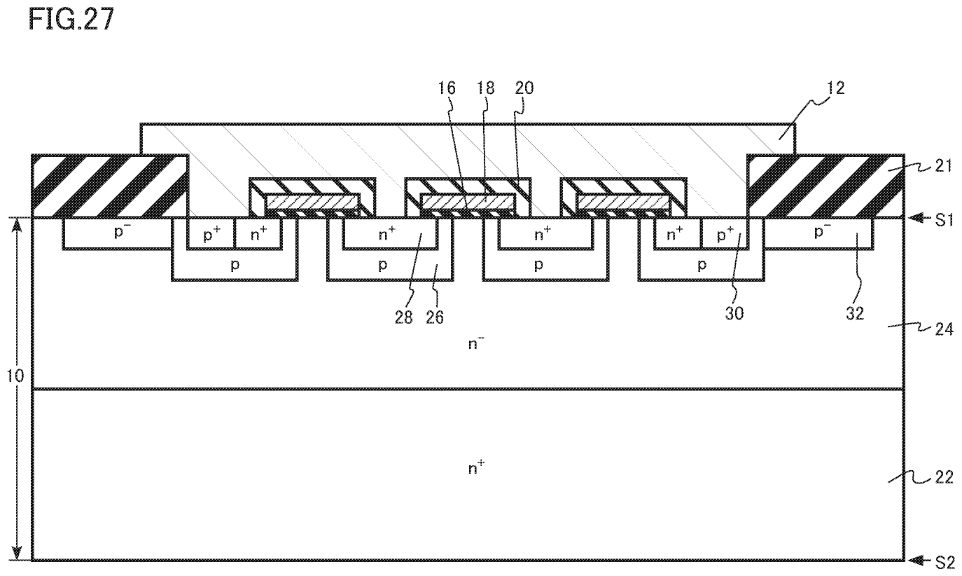

Next, the metal film 50 is patterned to form a source electrode 12 (FIG. 27). The patterning of the metal film 50 is performed by using, for example, the photolithography method and the dry etching method.

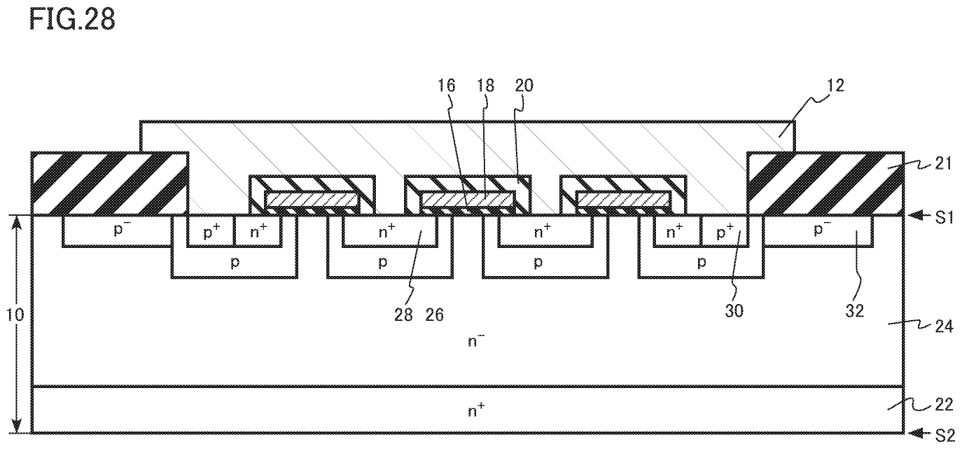

Next, back grinding of the silicon carbide substrate 10 is performed (FIG. 28). The silicon carbide substrate 10 is ground from the side of the back surface S2 to reduce the thickness of the silicon carbide substrate 10.

Next, the drain electrode 14 is formed on the back surface S2 of the silicon carbide substrate 10. The drain electrode 14 is formed by, for example, the sputtering method. The drain electrode 14 is, for example, a metal or a metal semiconductor compound.

The MOSFET 100 shown in FIG. 1 is manufactured by the above manufacturing method.

In the method for manufacturing the semiconductor device according to the second embodiment, the silicon film 52 is newly formed on the back surface S2 immediately after the heat treatment for activating the impurities. The silicon film 52 is formed before forming the first insulating film 44. That is, the silicon film 52 is formed before forming the peripheral insulating layer 21. The silicon film 52 is formed before forming the second insulating film 46 and the silicon film 48. That is, the silicon film 52 is formed before forming the gate insulating layer 16 and the gate electrode 18.

By newly forming the silicon film 52 on the back surface S2 immediately after the heat treatment for activating the impurities, alignment and edge detection can be performed by an optical sensor for a silicon substrate in a manufacturing step after the heat treatment.

In the method for manufacturing the semiconductor device according to the second embodiment, after removing the silicon film 52 and the silicon film 48 from the back surface S2 of the silicon carbide substrate 10, the metal film 50 for the source electrode 12 is formed on the front surface S1 of the silicon carbide substrate 10. The metal film 50 is opaque. Therefore, after the metal film 50 is formed, even when a silicon film does not exist on the back surface S2, alignment and edge detection can be performed by the optical sensor for the silicon substrate.

In addition, by removing the silicon film 52 and the silicon film 48 before forming the metal film 50, deformation of the silicon carbide substrate 10 due to stress can be suppressed. By suppressing the deformation of the silicon carbide substrate 10 due to the stress, it is possible to improve accuracy of pattern formation by photolithography, for example. Therefore, processing accuracy of the MOSFET 100 is improved.

The silicon film 52 and the silicon film 48 can be removed after the metal film 50 is formed and before the metal film 50 is patterned.

As described above, according to the method for manufacturing the semiconductor device according to the second embodiment, it is possible to facilitate alignment and edge detection of the silicon carbide substrate by providing the silicon film on the back surface, similarly to the first embodiment. Further, it is possible to facilitate alignment and edge detection of the silicon carbide substrate in more steps than those in the first embodiment. Further, the processing accuracy of the manufactured semiconductor device is improved.

### Third Embodiment

A method for manufacturing a semiconductor device according to the a third embodiment is different from a method for manufacturing a semiconductor device according to the first embodiment in that a first silicon film formed on a side surface of a silicon carbide substrate is remained when the first silicon film formed on a front surface of the silicon carbide substrate is removed. Hereinafter, some descriptions of the same contents as those of the method for manufacturing the semiconductor device according to the first or second embodiment may be omitted.

A semiconductor device manufactured by the method for manufacturing the semiconductor device according to the third embodiment is a planar gate type vertical MOSFET 100 using silicon carbide, similarly to the method for manufacturing the semiconductor device according to the first embodiment.

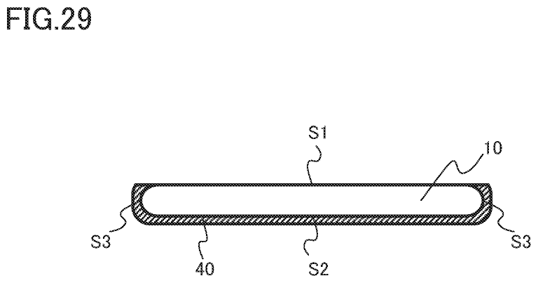

FIG. 29 is a schematic cross-sectional view showing the method for manufacturing the semiconductor device according to the third embodiment.

The same processing as the method for manufacturing the semiconductor device according to the first embodiment is performed until a silicon film 40 is formed so as to contact a front surface S1, a back surface S2, and a side surface S3 of a silicon carbide substrate 10.

Next, the silicon film 40 formed on the front surface S1 of the silicon carbide substrate 10 is removed. At this time, the silicon film 40 formed on the side surface S3 of the silicon carbide substrate 10 is remained (FIG. 29).

The silicon film 40 is removed by, for example, a chemical mechanical polishing method (CMP method). By using the CMP method, it becomes easy to leave the silicon film 40 formed on the side surface S3.

Instead of the CMP method, for example, after forming a protective film on the side surface S3 of the silicon carbide substrate 10, the silicon film 40 formed on the front surface S1 can be removed by isotropic dry etching.

The manufacturing method after removing the silicon film 40 formed on the front surface S1 of the silicon carbide substrate 10 is the same as the manufacturing method according to the first embodiment or the second embodiment.

There is a side surface detection type optical sensor in which, when alignment and edge detection of the substrate are performed, alignment and edge detection is performed by irradiating the side surface of the substrate with light instead of the back surface of the substrate. In the method for manufacturing the semiconductor device according to the third embodiment, the opaque silicon film 40 exists on the side surface S3 of the silicon carbide substrate 10. Therefore, in the method for manufacturing the semiconductor device according to the third embodiment, a semiconductor manufacturing device including the side surface detection type optical sensor can be used for manufacturing the MOSFET 100.

As described above, according to the method for manufacturing the semiconductor device according to the third embodiment, it is possible to facilitate alignment and edge detection of the silicon carbide substrate by providing the silicon film on the back surface, similarly to the first and second embodiments. Further, the semiconductor manufacturing device including the side surface detection type optical sensor can be used for manufacturing the semiconductor device.

### Fourth Embodiment

A method for manufacturing a semiconductor device according to the a fourth embodiment is different from a method for manufacturing a semiconductor device according to the first embodiment in that, after forming a first silicon film, the first silicon film in a center portion of a silicon carbide substrate in the first silicon film formed on a back surface of the silicon carbide substrate is removed. Hereinafter, some descriptions of the same contents as those of the method for manufacturing the semiconductor device according to the first or second embodiment may be omitted.

A semiconductor device manufactured by the method for manufacturing the semiconductor device according to the fourth embodiment is a planar gate type vertical MOSFET 100 using silicon carbide, similarly to the method for manufacturing the semiconductor device according to the first embodiment.

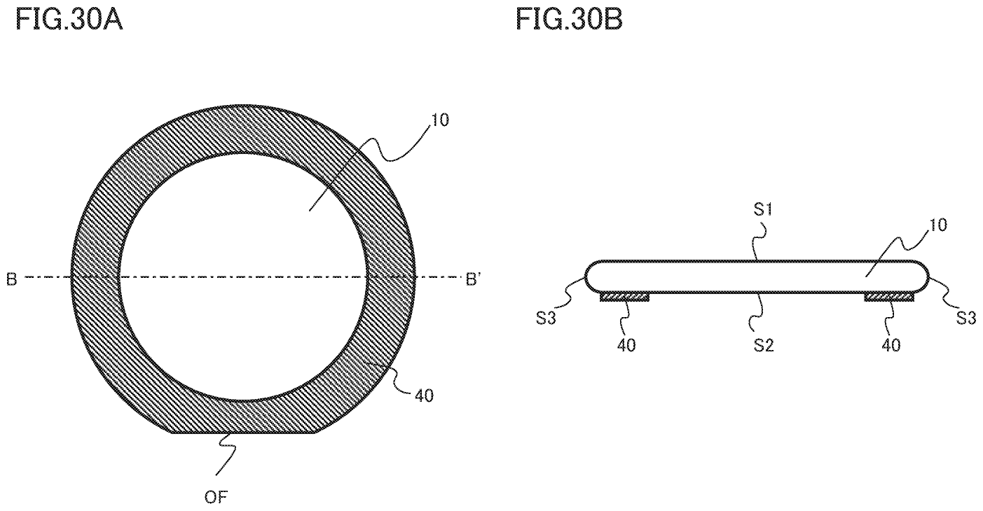

FIGS. 30A and 30B are schematic views showing the method for manufacturing the semiconductor device according to the fourth embodiment. FIG. 30A is a plan view of a silicon carbide substrate 10 and FIG. 30B is a cross-sectional view of the silicon carbide substrate 10.

The same processing as the method for manufacturing the semiconductor device according to the first embodiment is performed until a silicon film 40 formed on a front surface S1 of the silicon carbide substrate 10 is removed.

Next, the silicon film 40 in the center portion of the silicon carbide substrate 10 in the silicon film 40 formed on a back surface S2 of the silicon carbide substrate 10 is removed. In the silicon film 40 formed on the back surface S2, the silicon film 40 in a peripheral portion of the silicon carbide substrate 10 is remained.

Selective removal of the silicon film 40 in the center portion is performed by forming a protective film on the peripheral portion of the silicon carbide substrate 10 and then removing the silicon film 40 in the center portion by isotropic dry etching, for example.

FIG. 30A is a diagram of the side of the back surface of the silicon carbide substrate 10. FIG. 30B shows a cross-section taken along the line BB′ of FIG. 30A.

As shown in FIG. 30B, in the back surface S2 of the silicon carbide substrate 10, the silicon film 40 in the center portion of the silicon carbide substrate 10 is removed, and the silicon film 40 is remained only in the peripheral portion of the silicon carbide substrate 10.

The manufacturing method after removing the silicon film 40 in the center portion of the back surface S2 of the silicon carbide substrate 10 is the same as the manufacturing method according to the first embodiment, the second embodiment, or the third embodiment except that the silicon film 40 in the center portion of the back surface S2 does not exist.

In the method for manufacturing the semiconductor device according to the fourth embodiment, the silicon film 40 in the center portion of the back surface S2 is removed, so that deformation of the silicon carbide substrate 10 due to stress can be suppressed. Therefore, processing accuracy of the MOSFET 100 is improved.

As described above, according to the method for manufacturing the semiconductor device according to the fourth embodiment, it is possible to facilitate alignment and edge detection of the silicon carbide substrate by providing the silicon film on the back surface, similarly to the first embodiment. Further, the processing accuracy of the manufactured semiconductor device is improved.

In the first to fourth embodiments, the planar gate type vertical MOSFET has been described as an example of the manufactured semiconductor device. However, the semiconductor device is not limited to the planar gate type vertical MOSFET. For example, the manufactured semiconductor device can be any semiconductor device using a silicon carbide substrate, such as a trench gate type MOSFET, a Schottky barrier diode, a PiN diode, and a MOSFET containing a diode.

In the first to fourth embodiments, the case where the silicon film is exposed to the back surface S2 of the silicon carbide substrate 10 has been described as an example. However, for example, an insulating film such as a silicon nitride film can also be provided on the silicon film on the back surface S2.

In the first to fourth embodiments, the case where 4H—SiC is used as a crystal structure of SiC has been described as an example. However, the present disclosure can also be applied to a device using SiC of other crystal structure such as 6H—SiC and 3C—SiC.

While certain embodiments have been described, these embodiments have been presented by way of example only, and are not intended to limit the scope of the inventions. Indeed, the method for manufacturing the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming a first silicon film so as to contact a front surface, a back surface, and a side surface of a silicon carbide substrate, the back surface facing the front surface, the side surface being located between the front surface and the back surface;
removing the first silicon film formed on the front surface;
implanting impurities into the silicon carbide substrate from the front surface using an ion implantation method;
removing the first silicon film formed on the back surface, after the implanting the impurities; and
performing a heat treatment for activating the impurities, after the removing the first silicon film formed on the back surface.

2. The method for manufacturing a semiconductor device according to claim 1, wherein a temperature of the heat treatment is 1500° C. or more.

3. The method for manufacturing a semiconductor device according to claim 1, further comprising:
forming a second silicon film on the back surface, after the performing the heat treatment.

4. The method for manufacturing a semiconductor device according to claim 3, further comprising:
removing the second silicon film; and
forming a metal film on the front surface after the removing the second silicon film.

5. The method for manufacturing a semiconductor device according to claim 1, wherein the first silicon film formed on the side surface is remained after the removing the first silicon film formed on the front surface.

6. The method for manufacturing a semiconductor device according to claim 1, further comprising:
removing the first silicon film in a center portion of a silicon carbide substrate in the first silicon film formed on a back surface, before the implanting the impurities.

7. The method for manufacturing a semiconductor device according to claim 1, wherein the first silicon film is amorphous or polycrystalline.

8. The method for manufacturing a semiconductor device according to claim 1, wherein a thickness of the first silicon film is 500 nm or more and 2 μm or less.

9. A method for manufacturing a semiconductor device, comprising:
preparing a silicon carbide substrate having a front surface, a back surface facing the front surface, and a side surface located between the front surface and the back surface, the silicon carbide substrate having a first silicon film formed so as to contact the front surface, the back surface, and the side surface;
removing the first silicon film formed on the front surface;
implanting impurities into the silicon carbide substrate from the front surface using an ion implantation method;
removing the first silicon film formed on the back surface, after the implanting the impurities; and
performing a heat treatment for activating the impurities, after the removing the first silicon film formed on the back surface.

10. The method for manufacturing a semiconductor device according to claim 9, wherein a temperature of the heat treatment is 1500° C. or more.

11. The method for manufacturing a semiconductor device according to claim 9, further comprising:
forming a second silicon film on the back surface, after the performing the heat treatment.

12. The method for manufacturing a semiconductor device according to claim 11, further comprising:
removing the second silicon film; and
forming a metal film on the front surface after the removing the second silicon film.

13. The method for manufacturing a semiconductor device according to claim 9, wherein the first silicon film formed on the side surface is remained after the removing the first silicon film formed on the front surface.

14. The method for manufacturing a semiconductor device according to claim 9, further comprising:
removing the first silicon film in a center portion of the silicon carbide substrate in the first silicon film formed on the back surface, before the implanting the impurities.

15. The method for manufacturing a semiconductor device according to claim 9, wherein the first silicon film is amorphous or polycrystalline.

16. The method for manufacturing a semiconductor device according to claim 9, wherein a thickness of the first silicon film is 500 nm or more and 2 μm or less.
